(19) United States
(12) Patent Application Publication
(10) Pub. No.: US 2026/0136870 A1
(43) Pub. Date: May 14, 2026

(54) HIGH TEMPERATURE GAS SUPPLYING TYPE OF A PROCESSING SYSTEM

(71) Applicant: VM Inc., Icheon-si (KR)

(72) Inventors: Sang Woo LEE, Suwon-si (KR); Woo Hyung CHOI, Seongnam-si (KR); Joong Hyeon AHN, Hwaseong-si (KR); Sung Kyun JUNG, Suwon-si (KR)

(21) Appl. No.: 19/382,221

(22) Filed: Nov. 6, 2025

(30) Foreign Application Priority Data
Nov. 13, 2024 (KR) 10-2024-0160705

(51) Int. Cl. H01L 21/67; H01J 37/32

(52) U.S. Cl. CPC H10P 72/0421; H01J 37/3244; H01J 37/32357; H01J 2237/334

(57) ABSTRACT

Provided is a high temperature gas supplying type of a processing system. A high temperature gas supplying type of a processing system comprises a shower head 12 arranged to face an electrostatic chuck 13; a baffle 14 formed along an edge part of the shower head 12; a driving unit 16a, 16b for moving a substrate W up and down by moving an edge ring 15 up and down; and a high temperature gas supplying module GS for supplying a high temperature gas below the shower head 12.

### BACKGROUND OF THE INVENTION

### 1. Field of the Invention

The present invention relates to a high temperature gas supplying type of a processing system, in particular the processing system for performing an etching step of an ALE process efficiently by introducing a high temperature gas in an atomic layer etching process.

### Description of the Related Art

This work was supported by Next-generation Intelligence Semiconductor Foundation grant funded by the Korea government (the Ministry of Science and ICT, the Ministry of Trade, Industry and Energy) (RS-2024-00407627, Development of high-productivity and low-damage hybrid atomic layer etching equipment for sub-10nm Deep Trench Silicon architecture).

The semiconductor industry has developed for a long time in a direction to enhance a performance, to increase an integration and to reduce a cost through a miniaturization. However, as an ultra-fine process below 10 nm is developed, various physical and technical limits have been found. As a gap between transistors becomes narrower up to a degree of a few nanometers, a leak current increases rapidly, resulting in exacerbating a heat dissipation. Thereby, a signal interference and a wiring delay to reduce a device performance are brought about. Owing to such limitation of two dimensional plane structure, it is difficult to further improve an integration degree, and an attempt to integrate more elements within a given area increases a complexity of a process and leads to a higher defect rate. And also, as a semiconductor is made as a high performance chip, more power is required, and a heat generation issue may impact its performance and stability negatively. And, if the heat generation issue is not solved, it is difficult to satisfy high demands of computing and data centers.

In order to solve such problems, the semiconductor manufacturing process has attempted to transit to a 3D structure. The 3D structure may become a structure to enhance the integration degree by building up layers vertically to maximize the performance and to improve a power efficiency and a processing rate by shortening a signal path. In particular, DRAM or NAND memory adapts a structure of a cell stack structure with dozens of layers to provide more capacity within a given area, and therefore, precise etching technologies for processing each layer uniformly is required in order to produce a 3D structure with a high aspect ratio. And also, various elements may be stacked vertically by 3D packaging based on Through-Silicon Via (TSV) to achieve both high performance and miniaturization. And in case of multichip such as CPU, GPU or HBM, it has an advantage that a data transmitting delay and a power loss are reduced.

However, 3D process is much more complex than the known 2D process, and in particular, it is essential to etch each layer uniformly. When the known etching process based on plasma is applied, it has a danger that a substrate damage and an excessive etching occurs due to a use of high energy ions. On the contrary, a thermal atomic layer etching (ALE) process utilizing a thermal energy can decrease such danger significantly. The thermal ALE process can control the etching process precisely at the atomic level to maintain high precision in 3D element with high aspect ratio, and can minimize the substrate damage by inducing a chemical reaction with the thermal energy instead of the plasma. And also, the thermal ALE process is suitable for manufacturing an advanced device to utilize a new material such as a high dielectric coefficient material or a metal oxide, and has a strong point in view of a compatibility with various materials. Nevertheless, the thermal ALE process has a disadvantage that a process time is prolonged owing to a limitation of a thermal transfer rate, and thereby the productivity may be reduced. Therefore, it is necessary to develop a technology in order to improve a thermal transfer rate in the course of ALE process to shorten the processing time.

### PURPOSE OF THE INVENTION

An object of the present invention is to provide with a high temperature gas supplying type of a processing system to reduce a processing time by enhancing a heat transfer efficiency to a substrate during an ALE process.

### SUMMARY OF THE INVENTION

According to one embodiment of the present of the invention, a high temperature gas supplying type of a processing system comprises a shower head arranged to face an electrostatic chuck; a baffle formed along an edge part of the shower head; a driving unit for moving a substrate up and down by moving an edge ring up and down; and a high temperature gas supplying module for supplying a high temperature gas below the shower head.

According to other embodiment of the present invention, the high temperature gas supplying module comprises a hot gun for generating a high temperature gas and a mass flow controller.

According to another embodiment of the present invention, the system further comprises a gas line extending within a chamber from the high temperature supplying module, and a high temperature gas supplied along the gas line is sprayed to an upper surface of the substrate from a lower surface of the shower head.

According to still another embodiment of the present invention, the system further comprises a guiding path for guiding the high temperature gas to a first and second spraying path formed at a center part or an edge part of the lower surface of the shower head.

According to still another embodiment of the present invention, the system further comprises one or more spraying holes formed at the first and second spraying path.

According to still another embodiment of the present invention, the high temperature gas is a nitrogen, a helium, an argon or a clean dry air.

According to still another embodiment of the present invention, the system further comprises a manometer measuring a pressure of a process volume formed by the shower head and the substrate, and a flow rate of the high temperature gas is regulated to be supplied based on the pressure measured by the manometer.

### BRIEF DESCRIPTION OF THE DRAWINGS

FIG. 1 shows an embodiment of a high temperature gas suppling type of a processing system according to the present invention.

FIG. 2 shows an embodiment of a path for supplying a high temperature gas according to the present invention.

FIG. 3 shows another embodiment of a path for supplying a high temperature gas according to the present invention.

FIG. 4 shows an embodiment of a method for etching an atomic layer by supplying a high temperature gas according to the present invention.

### DETAILED DESCRIPTION OF EXEMPLARY EMBODIMENTS

Exemplary embodiments of the present invention will be described herein below with reference to the accompanying drawings.

The ALE (Atomic Layer Etching) process corresponds to a technology in which a reactive gas is adsorbed on a surface to be etched and an adsorbed gas is removed using an ion energy or a heat energy. Thereby, the atom bonded to an etching layer is removed and the etched surface is made physically smooth. The ALE process removes a thin layer of a material using a sequential self-limiting reaction, and is considered as one of the most promising technology for achieving a low process variability at an atomic level. A first step of such ALE process is to adsorb an etching gas on a surface to be etched for reacting after flowing the etching gas into a chamber. In such a step, radicals dissociated into a plasma are often used for improving an adsorbing rate of the etching gas. In first step, if the etching gas is sufficiently adsorbed on a thin film surface of a single layer, no more adsorbing reaction occurs by a self-limitation. A second step of the ALE process is to remove remaining gases except the gas adsorbed on the thin film surface. And a third step is to remove the reactive surface layer where the etching gas is adsorbed by heating the substrate on which the layer is formed by the surface adsorption. In this step, even if the heat energy is sufficient for removing the chemically modified layer, only reactive surface layer may be removed by the self- limitation if the heat energy is not sufficient for a base bulky material to be removed. And a fourth step of the ALE process is to remove the etching by-products in the chamber. Such four steps consist of one cycle, and the cycle must be repeated for etching to a required thickness or depth.

In such ALE process, it takes time for Ar gas to reach a reactive space through a RPS (remote plasma source) and a shower head, and a relatively large amount of gas is required for transferring a sufficient heat. And the ALE process may have a problem that a heat transfer efficiency can be reduced because the heat energy is consumed additionally until a temperature of Ar gas itself rises since Ar gas of a room temperature is used. The high temperature supplying type of a process system according to the present invention provides an efficient gas flow and heat transfer. The process system according to the present invention forms a dedicated passage capable of supplying the gas to a processing space formed by the shower head, an edge ring and a wafer at a lower part of the shower head to optimize the gas flow. And also, the system can enhance the heat transfer efficiency by spraying directly after pre-heating the gas in a way to inject the high temperature gas. This method can solve a problem of an initial low temperature to enable the heat to be transferred rapidly and efficiently. And also, the method for etching the substrate according to the present invention can reduce a processing time efficiently in the removing processing step to enhance a productivity. In particular, supplying the high temperature gas, the heat energy may be transferred to the substrate in a way of a conductivity, a convection or a radiation, and thereby, the heat energy can be transferred efficiently. The processing system according to the present invention may be applied to various type of ALE processes, but not limited to.

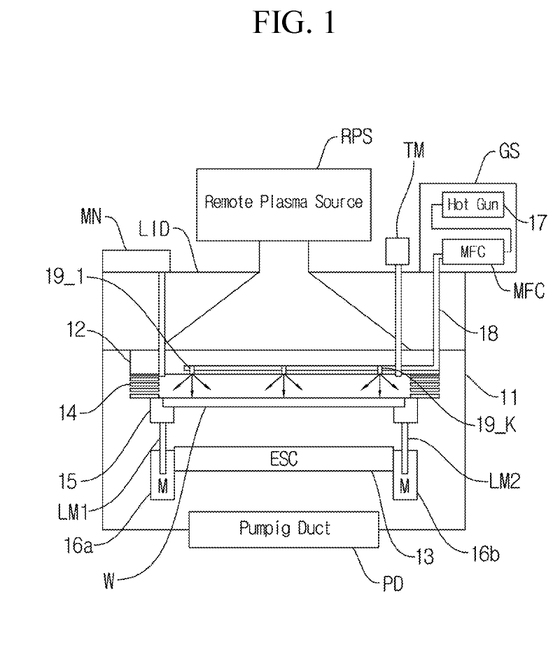

FIG. 1 shows an embodiment of a high temperature gas suppling type of a processing system according to the present invention.

Referring to FIG. 1, a high temperature gas supplying type of a processing system comprises a shower head 12 arranged to face an electrostatic chuck 13; a baffle 14 formed along an edge part of the shower head 12; a driving unit 16a, 16b for moving a substrate W up and down by moving an edge ring 15 up and down; and a high temperature gas supplying module GS for supplying a high temperature gas below the shower head 12.

The shower head 12 may be displaced at an upper part of a chamber 11, be made from an aluminum material and be heated to a temperature of up to 500° C. by an embedded internal heater which is not shown. The chamber 11 has an enclosed structure and can be maintained in a vacuum state in course of the ALE process. The ALE process may comprise the following steps: (i) adsorbing an active gas on a substrate such as a wafer; (ii) removing a remaining gas which has not been adsorbed; (iii) etching an adsorbed active surface layer; and (iv) removing the etching by-products within the chamber 11.

An upper part of the chamber 11 may be sealed with a lid (LID), and a plasma, which is generated at a remote plasma source RPS installed at an outside of the lid, may be introduced to an upper part of the shower head 12 through an inlet formed at the lid. The plasma introduced into the chamber 11 may be distributed into an inside of the shower head 12 uniformly. The shower head 12 may have a structure which allows ions and radicals to flow uniformly, and a plurality of circular holes may be formed at a center part and an edge part of the shower head 12. A size and a structure of the shower head 12 may be made in various ways according to a process to be performed, but not limited to.

The substrate W such as a wafer may be fixed at an upper part of the electrostatic chuck 13 in the adsorbing step of the ALE process, and the gas required for a reaction may be introduced from the remote plasma source RPS to an upper part of the shower head 12 arranged at the chamber 11. Thereafter, the gas reacting with the plasma may be dispersed on the upper surface of the substrate W fixed on the upper surface of the electrostatic chuck 13, and then, the gas may be adsorbed to form a deposition layer. When the adsorption is completed by self-limiting process, a remaining gas may be discharged. And when the remaining gas is discharged, then lift members LM1, LM2 may be elevated by an operation of driving units 16a, 16b to move the substrate W upward toward the shower head 12. Upper ends of the lift members LM1, LM2 may contact lower parts of an edge ring 15, and the lift member LM1, LM2 may move up and down by the operation of the driving units 16a, 16b such as a motor. After the substrate moves upward, a narrow volume may be formed by the shower head 12, a baffle 14 and the substrate W to proceed the removing step of the ALE process. The baffle 14 may have a shape to extend in a tilted way from a circular edge of the shower head 12, and a plurality of flowing holes or flowing slits may be formed in order to enable the gas to flow along a side direction. The narrow volume created by the shower head 12, the baffle 14 and the substrate W may become a volume for an etching process, and the shower head 12 may be heated by a heater disposed therein to provide a heat energy for removing the atomic layer.

According to one embodiment of the present invention, a gas supplying module GS for supplying a high temperature gas in course of removing an atomic layer may be installed, and the high temperature gas may be supplied to the lower part of the shower head 12 by the gas supplying module GS to be sprayed to the substrate. The high temperature gas supplying module GS may be installed at an outside of the chamber 11, and the high temperature gas supplying module GS may comprise a hot gun 17 to make the gas to a high temperature and a mass flow controller MFC to control an amount of the supplied gas. A gas line 18 may extend from the gas supplying module GS to an inside of the chamber 11, and the gas line 18 may be connected to a guiding passage formed at a lower part of the shower head 12. The guiding passage may be formed at the lower part of the shower head 12 in order that the gas supplied through the gas line 18 flows along the lower part of the shower head 12. The gas supplied from the hot gun 12 may become a nitrogen, a helium, an argon or a clean dry air, but not limited to. The gas supplied from the hot gun 17 may be made as a high temperature gas by the hot gun 17 to flow along the gas line 18, and the gas line 18 may be made from a stainless steel such as a material with a high heat transfer coefficient, and thereby, a temperature condition of the gas line 18 may be maintained as similar to that of the shower head 12 of a high temperature condition. Therefore, an independent means for heating the gas line 18 is not required according to the embodiment.

The gas flowing along the gas line 18 may flow along the guiding passage formed at the lower part of the shower head 12 to be guided to the center part and/or the edge part of the shower head 12. The high temperature gas flowing along the guiding path to the center part and/or the edge part of the lower part of the shower head 12 may be sprayed in the narrow volume through a plurality of spraying holes 19_1 to 19_K to the substrate W located at the lower part of the shower head 12. The pressure of the narrow volume may be measured by the manometer MN disposed at an outside of the chamber 11, and a measuring line may extend from the manometer MN disposed at an upper surface of the lid to an inside of the narrow volume after penetrating the lid and the shower head 12. An inner temperature of the narrow volume may be measured by a thermometer TM measuring a temperature in a non-contacting way. The thermometer TM may be displaced at an upper part of the lid, and a sensing line may extend to the inner of the narrow volume after penetrating the lid LID and the shower head 12. And a measuring hole formed at an end part of the sensing line may be sealed by a material such as a quartz. The mass flow controller MFC can control an amount of the high temperature gas supplied through the gas line 18 based on the pressure measured by the manometer MN. And also, a temperature of the high temperature gas heated by the hot gun 17 may be set based on the temperature measured by the thermometer TM.

The high temperature gas may be sprayed from the lower part of the shower head 12 in the removing step of the ALE process, and the gas whose temperature is lowered above the substrate W may be discharged through the baffle 14 together with by-products of the removing process. In this way, a heat may be delivered to the upper surface of the substrate W by the high temperature gas in a way of a conduction, a convection or a radiation to reduce a time for the etching process and to enhance a process efficiency. Specifically, the high temperature gas supplied through the gas line 18 may be sprayed directly to the narrow volume to transfer the heat energy to the substrate W, as the high temperature gas acts as a heat medium. In this process, the heat energy may not be lost and the removing step may be performed efficiently by supplying the high temperature gas. And also, as the by-products generate in the course of removing step and the gas missing the heat is discharged through the baffle 14, a new high temperature gas may refill the narrow volume continuously to reduce a time required for the etching process. And also, a flowing amount of the gas flowing through the narrow volume may be controlled correctly by the mass flow controller MFC. When the removing step is completed through such process, the etching by-products may be discharged through a pumping duct PD, as one cycle of the ALE process is completed. The etching by-products may be discharged through the pumping duct PD, but not limited to.

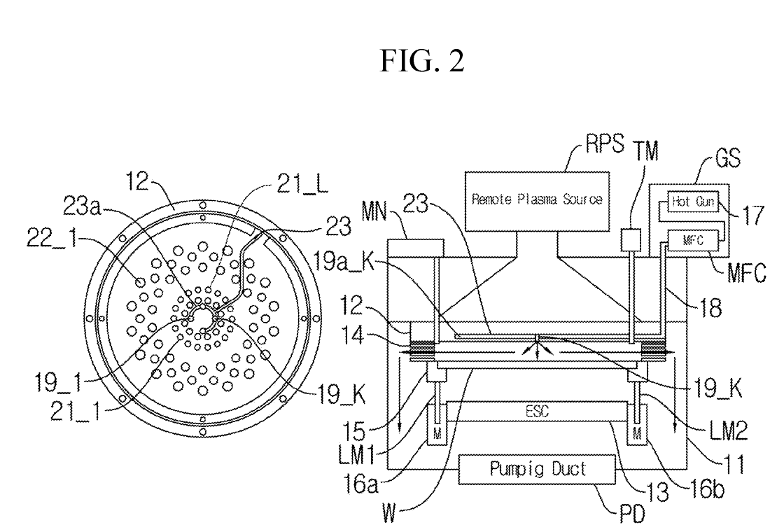

FIG. 2 shows an embodiment of a path for supplying a high temperature gas according to the present invention.

Referring to FIG.2, a lower part of the shower head 12 may have an overall circular plate shape, and a plurality of center holes 21_1 to 21_L may be formed at a center part. And also, a plurality of edge holes 22_1 to 22_M may be formed at an edge part of the shower head 12.

The center holes 21_1 to 21_L or the edge holes 22_1 to 22_M may be arranged in a circular form about a center of the lower surface of the shower head 11 and the center holes 21_1 to 21_L or the edge holes 22_1 to 22_M may be arranged along one or the more circles. The center holes 21_1 to 21_L or the edge holes 22_1 to 22_M may have a function to distribute the plasma containing a reactive gas uniformly above the substrate W. A gas line 18, which extends from the high temperature gas supplying module GS located outside the chamber 11 to an inside of the chamber 11, may be connected to a guiding path 23 formed at the lower part of the shower head 12. A high temperature gas supplied along the gas line 18 may flow along the guiding path 23, and the guiding path 23 may be formed to extend from the edge toward the center direction in a way to avoid the center holes 21_1 to 21_L and the edge holes 22_1 to 22_M. A spraying path 23a may be formed in a shape to surround the center of the shower head 12, and one or more spraying holes 19_1 to 19_K may be formed along the spraying path 23a. The spraying path 23a may be formed in a circular shape about the center of the shower head. The high temperature gas flowing along the guiding path 23 may flow along the spraying path 23a to be sprayed downward through the spraying holes 19_1 to 19_K. Thereby, a heat of the shower head 12 may be transferred to an upper part of the substrate W efficiently. In such a way, if the high temperature gas may be supplied to the center part of the shower head 12 to fill a center part of the narrow volume, then the etching by-products generated in the course of etching process may be pushed toward the edge to be discharged to the outside of the narrow volume through the baffle 14. The spraying path 23a may be formed in various structures, but not limited to.

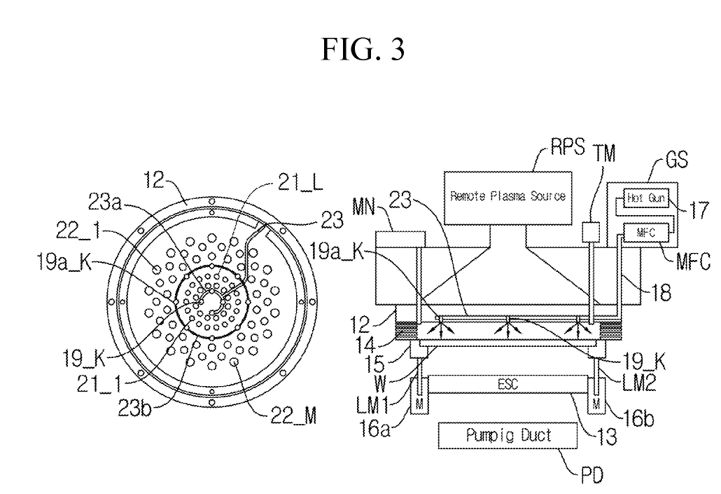

FIG. 3 shows another embodiment of a path for supplying a high temperature gas according to the present invention.

Referring to FIG. 3, the lower part of the shower head 12 may have a circular shape, a first spraying path 23a may be formed in a circular shape about a center of a circular plate shape, and a second spraying path 23b may also be formed at the edge part about the center of the lower part of the shower head 12. And a first spraying hole group 19_1 to 19_K and a second spraying hole group 19a_1 to 19a_N may be formed at the first spraying path 23a and the second spraying path 23b, respectively. The hot temperature gas flowing along the guiding path 23 may flow to the first spraying path 23a and the second spraying path 23 to be sprayed down the shower head 12 through the first spraying hole group 19_1 to 19_K and the second spraying hole group 19a_1 to 19a_N. In this way, if the high temperature gas may be supplied to the center part and the edge part, then a substrate temperature W may be changed rapidly and swiftly. The spraying paths 23a, 23b or the first and second spraying hole group 19_1 to 19_N, 19_1 to 19a_N may be formed in various ways, but not limited to.

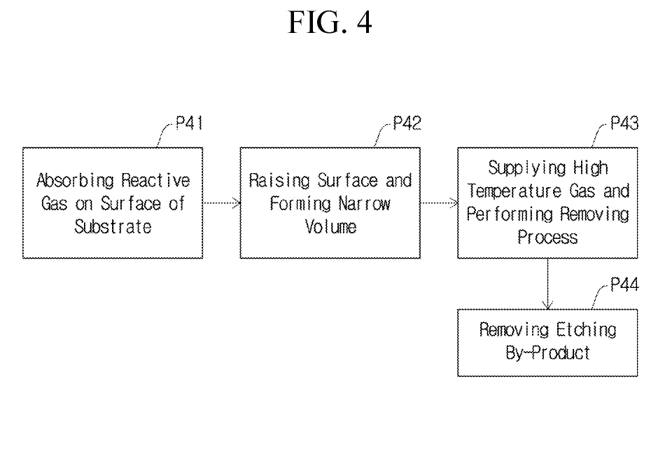

FIG. 4 shows an embodiment of a method for etching an atomic layer by supplying a high temperature gas according to the present invention.

Referring to FIG. 4, a method for etching an atomic layer by supplying a high temperature gas may comprise adsorbing a reactive gas on an upper surface of a wafer as a plasma is introduced within a processing chamber P41; raising the substrate after adsorbing the reactive gas and removing a residual gas, and forming a narrow volume corresponding to an etching processing volume and consisting of a shower head, a baffle and the substrate P42; supplying a high temperature gas down the shower head, and performing a process for removing an atomic layer by spraying the high temperature to the substrate from the shower head P43; and removing by-products after the process for removing is completed.

In order to perform the removing process in the narrow volume, the shower head may be heated by a heater installed within the shower head, and the high temperature gas may be heated to a temperature corresponding to that of the shower head. The high temperature gas may be supplied to the lower part of the shower head through a suitable gas line from an outside of the narrow volume, and the high temperature gas may be sprayed from the lower part of the shower head to the upper surface of the substrate to transfer the heat energy of the shower head to the substrate efficiently. The high temperature gas may be supplied to the shower head in various ways, but not limited to.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. A high temperature gas supplying type of a processing system comprising:
a shower head arranged to face an electrostatic chuck;
a baffle formed along an edge part of the shower head;
a driving unit for moving a substrate up and down by moving an edge ring up and down; and
a high temperature gas supplying module for supplying a high temperature gas below the shower head.

2. The system according to claim 1, wherein the high temperature gas supplying module comprises a hot gun for generating a high temperature gas and a mass flow controller.

3. A system according to claim 1, wherein the system further comprises a gas line extending within a chamber from the high temperature supplying module, and a high temperature gas supplied along the gas line is sprayed to an upper surface of the substrate from a lower surface of the shower head.

4. The system according to claim 1, wherein the system further comprises a guiding path for guiding the high temperature gas to a first and second spraying path formed at a center part or an edge part of the lower surface of the shower head.

5. The system according to claim 1, wherein the system further comprises one or more spraying hole formed at the first and second spraying path.

6. The system according to claim 1, wherein the high temperature gas is a nitrogen, a helium, an argon or a clean dry air.

7. The system according to claim 1, wherein the system further comprises a manometer measuring a pressure of a process volume formed by the shower head and the substrate, and a flow rate of the high temperature gas is regulated to be supplied based on the pressure measured by the manometer.
